(19) United States
(12) Patent Application Publication
(10) Pub. No.: US 2005/0288877 A1
(43) Pub. Date: Dec. 29, 2005

(54) Method and apparatus for instrument transformer reclassification

(75) Inventors: Paul E. Doig, Victoria (CA); Martin A. Hancock, Victoria (CA); Colin N. Gunn, Victoria (CA); J. Bradford Forth, Victoria (CA); Peter C. Cowan, Victoria (CA); Simon H. Lightbody, Victoria (CA); Marcie L. Cochrane, Victoria (CA); Stewart J. Harding, Victoria (CA); Daniel N. Loewen, Sidney (CA)

Correspondence Address: WORKMAN NYDEGGER;(F/K/A WORKMAN NYDEGGER & SEELEY), 60 EAST SOUTH TEMPLE, 1000 EAGLE GATE TOWER, SALT LAKE CITY, UT, 84111, US

(73) Assignee: Power Measurement Ltd.,

(21) Appl. No.: 11/043,403

(22) Filed: Jan. 25, 2005

Related U.S. Application Data
(63) Continuation-in-part of application No. 10/877,742, filed on Jun. 25, 2004.

(51) Int. Cl. G01R 21/00

(52) U.S. Cl. 702/60

(57) ABSTRACT

Systems and methods for reclassifying instrument transformers. A line mounted device that includes a sensor that can be attached to a power line. The line mounted device generates data or representations of the power parameters of the power line. A processor in the line mounted device produces modified representations of the power parameters that are transmitted wirelessly to a microprocessor based device. The microprocessor based device also receives second representations of the power parameters from legacy instrumentation. Compensation data is produced based on the modified representations from the line mounted device and the second representations from the legacy instrumentation. The compensation data can be used to compensate or correct the representations of the power parameters from the legacy instrumentation even after the line mounted device is no longer attached to the power line.

### CROSS-REFERENCE TO RELATED APPLICATIONS

This application is a continuation in part under 37 C.F.R § 1.53(b) of U.S. patent application Ser. No. 10/877,742, filed Jun. 25, 2004 (pending), the entire disclosure of which is hereby incorporated by reference.

### BACKGROUND OF THE INVENTION

1. The Field of the Invention

The present invention relates to systems and methods for measuring a power parameter on a high voltage power line. More particularly, the present invention relates to systems and methods for improving the accuracy of measurement of power parameters on a high voltage power line including compensating for inaccuracies in the output of instrument transformers designed for connection to power lines of 10 kV or higher.

2. Background and Relevant Art

Instrument transformers for installation on high voltage power lines, which may include those transformers used for protective relaying and metering, are large and expensive. This is especially true at higher power line voltages. For instance, instrument transformers for installation on 230 kV lines may cost more than $100,000 U.S. each. Replacement of instrument transformers is thus very costly in terms of capital costs. It is also very costly to replace instrument transformers due to the necessity to power down the power line while doing so. The large size of the instrument transformers also means that installation/removal and transportation costs are high.

It is quite common in legacy installations (such as at a substation) that the only instrument transformers that are installed are those used for protective relaying. These instrument transformers are typically designed to operate during large fault currents or voltages and are therefor not optimized for accuracy at normal currents and voltages. For example a relaying current transformer may have a large magnetic core and high core losses.

When instrument transformers optimized for metering applications are provided in an installation, they may be subject to degradation in accuracy over time. This may be due to magnetization from surge voltages or currents, insulation breakdown, degradation due to environmental stresses, etc.

It is therefor common in legacy installations to have inaccuracies in the measurement of voltage, current and therefore power flow due to the degradation and/or inherent inaccuracy of the installed instrumentation.

### BRIEF SUMMARY OF THE INVENTION

The present invention is defined by the following claims, and nothing in this section should be taken as a limitation on those claims. By way of introduction, the preferred embodiments described below relate to systems and methods for measuring power parameters of a power line and more particularly to systems and methods for improving the accuracy of or correcting the measurements of power parameters monitored by legacy instrumentation.

One embodiment includes a method for reclassifying legacy instrumentation. The method couples a first line device to a power line and a second line device to the legacy instrumentation. First data representing at least one power parameter is generated with the first line device and second data representing the at least one power parameter is generated using the second line device. Transfer characteristics of the legacy instrumentation are then identified based on at least the first data and the second data.

Another embodiment includes a method for reclassifying a current transformer in a legacy instrumentation. The method includes connecting a first line device on a bus line associated with a particular transmission line, wherein the bus line includes one or more current transformers. The method connects a second line device on a secondary of a particular current transformer. In the method, the second line device is similar to the first line device. The method then determines transfer characteristics of the particular current transformer by comparing first data measured by the first line device for current in the bus line with second data measured by the second line device. Next, the method reclassifies the particular current transformer based on the transfer characteristics.

Another embodiment includes a system for reclassifying the legacy instrumentation. The system includes a first line device operative to couple to the power line and monitor at least one parameter of the power line. The first line device generates first data indicative of the at least one parameter of the power line. The system also includes a second line device operative to interface with the legacy instrumentation and monitor the at least one parameter of the power line at the legacy instrumentation. The second line device generates second data indicative of the at least one parameter of the power line at the legacy instrumentation. In the system, a microprocessor based device is coupled with the first line device and with the second line device. The microprocessor based device identifies one or more transfer characteristics of the legacy instrumentation based on the first data and the second data.

Another embodiment includes a system for reclassifying a current transformer. The system has a first line device operative to couple with a particular bus line in the power station. The first line device generates first characteristics relating to current in the particular bus line. In the system, a second line device is operative to couple with a secondary of a particular current transformer connected with the particular bus line and the second line device generates second characteristics relating to current in the particular current transformer. The system also includes a microprocessor device coupled with the first line device and the second line device such that current flow through the particular current transformer is characterized using the first characteristics and the second characteristics.

Another embodiment of the invention includes a method for correcting power parameters measured by legacy instrumentation. The method attaches a sensor to a transmission line. The method then monitors one or more power parameters of The transmission line with the sensor and detects a transient condition in the transmission line with the sensor. The method then determines if characteristics of the legacy instrumentation have changed in response to the transient condition and reclassifies the legacy instrumentation if the characteristics have changed.

Further aspects and advantages of the invention are discussed below in conjunction with the preferred embodiments.

### BRIEF DESCRIPTION OF THE DRAWINGS

In order to describe the manner in which the above-recited and other advantages and features of the invention can be obtained, a more particular description of the invention briefly described above will be rendered by reference to specific embodiments thereof which are illustrated in the appended drawings. Understanding that these drawings depict only typical embodiments of the invention and are not therefore to be considered to be limiting of its scope, the invention will be described and explained with additional specificity and detail through the use of the accompanying drawings in which:

FIG. 1 depicts a block diagram of one embodiment of the apparatus of the present invention;

FIG. 2 depicts a flow diagram of an exemplary method of improving accuracy of legacy instrumentation;

FIG. 3 depicts one embodiment of the apparatus in operation;

FIG. 4 illustrates one embodiment of a reclassification system that uses a line mounted sensor and a ground sensor integrated with legacy instrumentation; and

FIG. 5 illustrates examples of line mounted devices used to reclassify current transformers in legacy instrumentations.

### DETAILED DESCRIPTION OF THE PREFERRED EMBODIMENTS

Herein, the phrase “coupled with” is defined to mean directly connected to or indirectly connected through one or more intermediate components. Such intermediate components may include both hardware and software based components. Further, to clarify the use in the pending claims and to hereby provide notice to the public, the phrases “at least one of <A>, <B>, . . . and <N>” or “at least one of <A>, <B>, . . . <N>, or combinations thereof” are defined by the Applicant in the broadest sense, superceding any other implied definitions herebefore or hereinafter unless expressly asserted by the Applicant to the contrary, to mean one or more elements selected from the group comprising A, B, . . . and N, that is to say, any combination of one or more of the elements A, B, . . . or N including any one element alone or in combination with one or more of the other elements which may also include, in combination, additional elements not listed.

Examples of the present invention provide systems and methods for improving the accuracy of monitoring of voltage, current and power flowing in power lines. These power lines typically include three-phase transmission and distribution lines of 10 kV and up. One embodiment of an apparatus includes a line mounted device that can be temporarily or permanently attached to a power line. The line mounted device may be mounted to a transmission conductor, bus bar, jumper, or any other conductor carrying the voltage and/or current of the power line as appropriate. The line mounted device measures at least one of voltage, current and power flowing in the power line. The apparatus further includes a microprocessor device capable of comparing the output of the line mounted device with the output of the legacy instrumentation, which is already installed and monitoring the power line. The microprocessor based device is further operative to produce an output that is usable to compensate the output of the existing legacy instrumentation such that after the line mounted device is removed from the power line, accurate measurement of voltage, current and/or power is still possible with the legacy instrumentation. The microprocessor based device may be a computer, computing device, and/or IED such as an existing digital power meter, protective relay, etc., that is capable of receiving communication from the sensor.

One implementation of the sensor may be the HVTLAD described in U.S. patent application Ser. No. 10/774,088 entitled “BODY CAPACITANCE ELECTRIC FIELD POWERED DEVICE FOR HIGH VOLTAGE LINES” which is incorporated by reference herein. Alternatively, the sensor may be powered by current flow in the power line, a battery, solar power, wind power or other energy source. Any of these energy sources may be complemented by a large value capacitor (typically referred to as a supercapacitor). The supercapacitor may store energy while the device is operating in a low power mode and deliver energy in order that the device may periodically perform operations that require more energy.

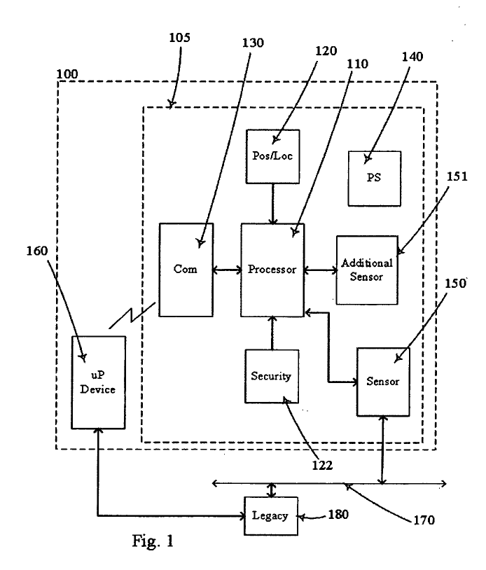

FIG. 1 shows a reclassification apparatus 100. The reclassification apparatus 100 includes a line mounted device 105. The line mounted device 105 is operative to be coupled to a power line 170. A sensor 150 within the line mounted device 105 senses at least one of voltage, current and power flowing in the power line 170. The sensor 150 may comprise appropriate amplifiers, circuitry, analog to digital converters, etc., to produce a digital representation of the voltage, current, power flow and/or other parameters of the power line 170. The line mounted device 105 may include other sensors 151 included in the line mounted device 105. These other sensors 151 may detect temperature, humidity, wind speed, and the like or any combination thereof. Alternatively, these factors can be determined independently of the line mounted device 105.

A processor 110 couples to the sensor 150 and is operative to receive this digital representation of the voltage, current, and/or power. The processor 110 may also receive a digital representation of other data including temperature, humidity, wind speed, line sag, and the like. The processor 110 may perform calibration, rms calculations, compensations, phase calculations, etc., on the digital representation to produce modified digital representations. The modified digital representations are communicated via communication circuitry 130 to a microprocessor based device 160. The communications pathway between the communication circuitry 130 and the microprocessor device 160 may be a wireless link such as Bluetooth®, wireless telephone, or other radio frequency wireless links.

In the process of generating the modified digital representations, the processor 110 may include position and or time information provided by time/position circuitry 120. The time/position circuitry 120 may be, for example, a global positioning satellite (GPS) receiver that determines accurate time and position using global positioning satellites. The time/position circuitry may also be comprised within communications circuitry 130 such as wireless telephone circuitry. Alternatively, time/position circuitry 120 may be replaced by accurate time circuitry such as an atomic clock module coupled to the processor 110 if position is not important in the particular application.

The line mounted device 105 comprises a power source 140 to provide operating power to the circuitry within the line mounted device 105. As described above, the power source 140 may derive power from a body capacitance coupled to the power line 170, a battery or other appropriate power source.

Legacy instrumentation 180 also couples to the power line 170. The legacy instrumentation 180 may comprise current transformer(s), voltage transformer(s), power meter(s), protective relay(s), etc. The legacy instrumentation 180 produces output or readings (including measurements of voltage, current, and/or power in the power line 170) that may be in error due to age, deterioration, operating range, etc., of the legacy instrumentation 180 as described above. At least the metering portion of the legacy instrumentation 180 may be comprised within the microprocessor based device 160.

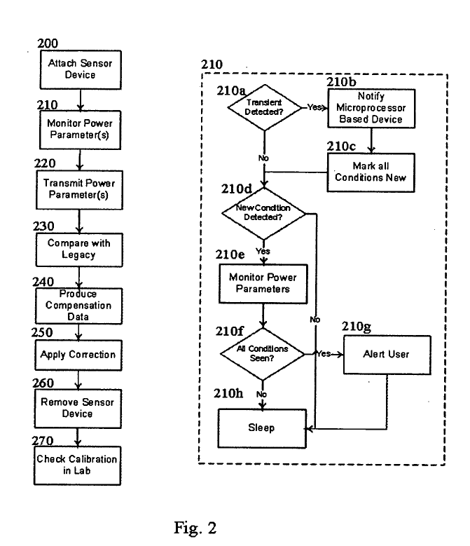

FIG. 2 shows an exemplary method for using the reclassification apparatus 100 to improve the accuracy of readings from the legacy instrumentation 180. The apparatus 100 may include a line mounted device 105, which is one embodiment of a monitoring device. The line mounted device 105 is attached to the power line 170 (block 200). This may be done by “hot-sticking” the line mounted device 105 to the power line 170 while the power line 170 is live or by other appropriate methods. “Hot-sticking” the line mounted device may be done by individual(s) in a bucket truck or from the ground. In order to facilitate the “hot-sticking” method, the line mounted device 105 may be of “clamp-on” variety where for instance any current transformers within the line mounted device 105 have a split core allowing the reclassification apparatus to be clamped around the power line 170 or may comprise a solid core current transformer wherein the power line 170 is disconnected before installation of the line mounted device 105. The line mounted device 105 then monitors at least one power parameter in the power line (block 210). Power parameters may include, but are not limited to, rms voltage, rms current, voltage samples, current samples, watts, VARs, VAs, and the like or any combination thereof. The line mounted device 105 may timestamp the power parameters using time/position circuitry 120. In addition, the line mounted device 105 may determine a phase of the voltage and/or current in the power line 170. The phase of the voltage and/or current may be with respect to a reference such as the time from time/position circuitry 120 or may be with respect to the other of current and voltage. The line mounted device 105 may comprise an active current transformer as described in U.S. patent application Ser. No. 10/803,411 entitled “POWER LINE SENSORS AND SYSTEMS INCORPORATING SAME” which is incorporated by reference herein.

The line mounted device 105 transmits the at least one power parameter using communications circuitry 130 to the microprocessor based device 160 (block 220). The microprocessor based device 160 may have a memory that enables it to store multiple values of the at least one power parameter. The microprocessor based device 160 also receives and stores power parameters from the legacy instrumentation. Over a time period (for example one hour, one day, one week, one month, one year, etc.) the microprocessor based device 160 compares the power parameters received from the line mounted device 105 with the power parameters received from the legacy instrumentation 180 (block 230). The time period may be selected such that the power line will transition through most or all of its normal range of operation. The utility operating the power line 170 may also cycle the power line 170 through a range of operating current, voltage levels, etc. This may be done by changing the routing of power within the grid, ramping up or down generators located on the grid, opening/closing breakers within a substation, etc. The microprocessor based device 160 then produces compensation data that will facilitate correction of the power parameter measurement of the legacy instrumentation 180 (block 240). The compensation data is based, in one example, on the power parameters received from the line mounted device 105, the power parameters received from the legacy instrumentation 180, and/or a comparison of these power parameters.

The correction of the power parameters received from or generated by the legacy instrumentation may occur in several ways. The microprocessor based device 160 may receive the power parameter measurements of the legacy instrumentation 180 and produce corrected measurements using the compensation data. This may be accomplished using algorithms similar to those described in U.S. Pat. No. 6,671,635 entitled “Systems for Improved Monitoring Accuracy of Intelligent Electronic Devices” which is incorporated by reference herein. In another embodiment, the legacy instrumentation 180 may already contain correction algorithms in which case the legacy instrumentation 180 may be configured to use the new compensation data generated by the microprocessor based device 160. This may be facilitated by an instrument transformer correction function such as described on pages Instr Xformer Correction (ITC) Module −1 to 5 in the document entitled “ION Reference” published in March 2004 by Power Measurement located in Saanichton, B.C., Canada which is incorporated by reference herein. The microprocessor based device 160 may alternatively or in addition correct voltages and currents sample by sample, by phase, by frequency response, by power factor, using polynomial or other types of interpolation, using multiple calibration constants depending on load, based on temperature or humidity measurements, and the like or any combination thereof. For instance it may be found that a CT has a non-linear amplitude transformation ratio which is primarily based on the input signal amplitude, but also dependent on temperature. The line mounted device 105 may thus accurately measure amplitude and temperature which are reported to the microprocessor based device 160 and a multidimensional correction of the characteristics of the legacy CT may be determined based on these parameters. The data transmitted from the line mounted device 105 to the microprocessor based device 160 may include data indicative of voltage, current or power in the time domain or frequency domain.

The correction of the power parameters may then be applied on an ongoing basis (block 250). A power customer may thereafter be billed for their power usage based on the corrected power parameters. The line mounted device 105 may be removed (block 260) from the power line 170. Alternatively, the line mounted device 105 may be left on the power line 170. If the line mounted device 105 is left on the power line 170, it may be considered part of legacy instrumentation 180 to which the procedure of the present invention may be applied to in the future. This helps to compensate for any degradation of accuracy that may occur over time in the line mounted device 105 that has been permanently installed.

After the line mounted device 105 has been removed from the line, it may be taken to a laboratory and connected to a test set to verify that the line mounted device is still accurate (block 270). If it is still accurate, the correction factors to be used are thus validated. If not, the process may be restarted after the line mounted device 105 is re-calibrated. If the line mounted device 105 comprises a current sensor, the laboratory tests may include injecting a known current with a known phase with respect to a reference and comparing these known values to the output of the line mounted device 105.

Alternatively, the line mounted device 105 may monitor power parameters only under certain conditions. For example if a transient (such as a current surge, lightning strike, etc.) is detected (block 210a), the line mounted device 105 may notify the microprocessor based device 160 of this occurrence (block 210b). Under this condition, it may be determined that the characteristics of the legacy instrumentation 180 may have changed due to the transient and therefore, previous comparisons of the legacy instrumentation 180 output and the line mounted device 105 output may be discarded (block 210c). Alternatively, a more steady state condition such as high levels of harmonics may be detected by the line mounted device 105 which may indicate that some comparison algorithms may (at least temporarily) be unusable.

The characteristics of the legacy instrumentation 180 may change over time due to other influences (for example temperature, humidity, long term drift, etc.). If, for example, the legacy instrumentation 180 and line mounted device 105 are detecting current in the power line 170, the microprocessor may flag occurrences when the line mounted device 105 indicates the same current is flowing in the power line 170 as a previous measurement, but the legacy instrumentation 180 does not have the same output (within a desired accuracy specification) as previously. This may be an indication that reclassification of the legacy instrumentation to the desired accuracy may not be possible or additional influences may need to be taken into account.

The line mounted device 105 may also only monitor power parameters when the power line 170 is in a state not previously measured (for instance current is at a magnitude that has not been detected by the line mounted device 105 before). If a new condition is detected (210d), the power parameters are monitored (block 210e). The line mounted device 105 or microprocessor based device 160 may determine that all necessary conditions of the power line 170 have been seen (block 210f) (for instance, the power line has transitioned through various current levels such as 1-5A, 5-50A, 50-200A, etc.). In this case, an indication may be given to a user that the process is complete (block 210g). The monitoring process concludes with the line mounted device 105 going into a power saving sleep mode (210h). The line mounted device 105 may exit the sleep mode after a given passage of time or may detect a new condition during sleep mode and only wake up if a new condition is detected.

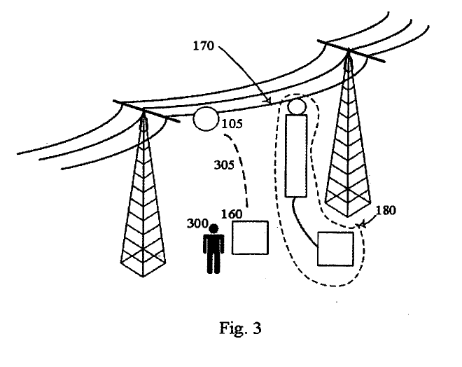

FIG. 3 depicts the reclassification apparatus 100 in operation. A line worker 300 facilitates testing of the accuracy of legacy instrumentation 180 which is monitoring power in a power line 170 using the line mounted device 105. For example, the legacy instrumentation 180 may be an energy meter with current transformers coupled to the power line. In order to ensure the legacy instrumentation 180 is correctly calibrated or to compensate for inaccuracy in the legacy instrumentation 180, the line worker 300 attaches the line mounted device 105 to the power line 170, thereby allowing the line mounted device 105 to accurately monitor the power parameters in the power line over a period of time, such as 1 hour. A microprocessor device 160, such as a laptop computer or any other microprocessor based device, wirelessly couples 305 with the line mounted device 105 that has just been installed. As the line mounted device 105 monitors the power parameters in the power line 170, the information is transmitted either in real time, on demand, or on set intervals from the communications circuitry located in the line mounted device 105 to the microprocessor device 160. The information may include timestamps. In an alternate example, the line mounted device 105 contains memory circuitry to store time-stamped power parameter data which may be compared with power parameter data from the legacy instrumentation at a later time. Upon conclusion of the testing, or during the testing, the microprocessor based device compares the power parameter data as measured by the line mounted device 105 to the power parameter data as measured by the legacy instrumentation 180 and creates compensation data or characteristics for the legacy instrumentation 180 to utilize. As discussed earlier, the power parameter data may be time stamped to aid in the compensation characteristic calculations.

In another example, the legacy instrumentation 180 itself also acts as the microprocessor based device 160 and communicates to the line mounted device 105 through a wireless connection. In this example, the legacy instrumentation 180 performs and implements the compensation characteristic calculations. Alternately, data, that may include but is not limited to, power parameters, and/or compensation data or characteristics, is loaded into a first device 160, such as a portable energy meter, laptop or other portable computing device, and then transferred into the legacy instrumentation 180, ultimately allowing the legacy instrumentation 180 to perform the compensation characteristic calculations with its own microprocessor based on the power parameter data measurements of the line mounted device 105 and the power parameter data measurements of the legacy instrumentation 180.

In another example the line mounted device 105 incorporates wireless circuitry, such as cellular telephony circuitry, that enables it to communicate with the legacy instrumentation 180 to continue to compensate for the legacy instrumentation 180 measurement drift or error. In operation the line mounted device 105 is coupled to the power line 170 through methods known for attaching devices to power lines, such as a “hot stick”. The line mounted device 105 then utilizes the wireless circuitry to communicate the sensor power parameter data to a microprocessor device 160, which also contains the legacy instrumentation 180 power parameter data. It can be appreciated that the microprocessor device 160 can be either an element of the legacy instrumentation 180 or a separate device. Next compensation characteristics for the legacy instrumentation 180 to utilize are created. Once the initial power parameters have been recalibrated for the legacy instrumentation 180, the line mounted device 105 periodically (such as weekly or monthly) sends new time stamped power parameter data to the microprocessor device 160, which checks for drift errors in the legacy instrumentation 180 power parameter data. When the drift exceeds a predetermined threshold, such as 0.2%, 2%, etc. error, then new compensation characteristics are calculated by the microprocessor device 160.

The sensor 150, may contain a limitation for the time or number of uses that it can be used before it ceases operation. Given the large cost savings the reclassification apparatus 100 can facilitate, it may be advantageous for the manufacturer of the reclassification apparatus 100 to limit or control the use of the reclassification apparatus 100, and thus be in the position to charge on a per use basis, instead of for the one time sale of the reclassification apparatus 100. In a first example for limiting the use of a sensor or of the line mounted device 105 may contain a security module 122 coupled to the microprocessor which controls the power parameter collection from the sensor 150 and power line 170. It can be appreciated that the security module can be a hardware security module requiring a hardware key, such as a dongle type key, or a software key requiring a user communicate an activation code to the line mounted device 105, through its communication circuitry 130. In a second example the security module 122 limits the use of the line mounted device 105 based on time. For example the line mounted device 105 may only measure the power parameters on the power line 170 for a period of 30 days before it needs to be reset either at the factory, or through another automated reset method dictated by the security module 122 as described above. Alternatively, the reclassification apparatus 100 or line mounted device 105 may operate only for a fixed number of reclassification cycles (such as an integer multiple of 3 for 3 phase systems). In a third example the security module 122 encrypts the power parameter data before transmitting it using the communications circuitry 130, thereby requiring the recipient to have the decryption key. It can be appreciated that this encryption may be rotated on a per-use basis of the device and the new decryption key may be reacquired from the manufacturer for every subsequent use. The security module 122 may be implemented through appropriate code executing on the processor 10.

The line mounted device 105 or reclassification apparatus 100 may communicate through appropriate networks such as the Internet, satellite, and or cellular telephone networks to a central server. The central server may also receive readings from the legacy instrumentation 180. The central server may thus generate compensation data or characteristics to be returned to the legacy instrumentation 180. Alternatively, the central server may continue to receive readings from the legacy instrumentation 180 and generate compensated readings. These readings may be returned by appropriate networks to the owner of the legacy instrumentation 180. In this scenario, the central server may be located at a facility owned by the provider of the reclassification apparatus 100 or another service provider. It will be appreciated that the central server may implement the security mechanisms previously described by for instance, only providing the compensation data for a fixed period of time from a given reclassification apparatus 100 or line mounted device 105 to the customer or legacy instrumentation 180.

It will be clear that various modification to the foregoing detailed description of the invention are possible without departing from the spirit and scope of the invention. For instance, the functionality of the microprocessor device 160 may be integrated into the sensor 105 or the legacy instrumentation 180. In addition, the sensor may retrieve data from the legacy instrumentation 180 over a wireless or other appropriate link and produce compensation data that is immediately or later incorporated into the legacy instrumentation 180 calculations. The legacy instrumentation 180 or microprocessor device 160 may comprise time circuitry to receive a time reference from a GPS satellite, cellular phone network, etc. This time reference may be synchronized with the time reference received by time/position circuitry 120. This time reference may be used to associate time with measurements, calculations, etc. generated by the legacy instrumentation 180 or microprocessor device 160.

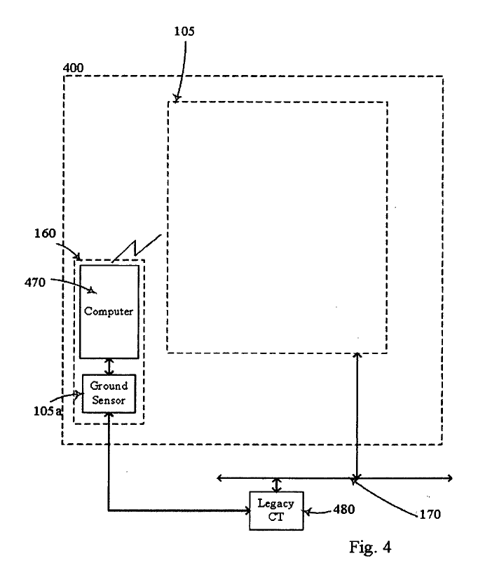

Referring now to FIG. 4, one embodiment of the reclassification apparatus 400 is shown coupled to the power line 170 and a legacy current transformer 480 which is a specific type of legacy instrumentation 180. Unless claimed as such the invention is not limited to this embodiment and this implementation is provided by way of example only.

In this implementation, the microprocessor based device 160 is split into two sections. A computer 470 interfaces through wireless communications to the line mounted device 105 and via wired or wireless communications to a ground sensor 105a. The ground sensor 105a, as described below, is substantially similar or the same as a line mounted device 105. The ground sensor 105a interfaces to the legacy CT 480. The ground sensor may have almost identical circuitry as the line mounted device 105. The only difference may be that the ground sensor 105a has a sensor input operative to receive the signal range of the legacy current transformer 480, whereas the line mounted device 105 monitors current flow in the power line 170 directly. In one embodiment, the ground sensor 105a may differ from the line mounted device 105 primarily in nominal current input specification. This may be implemented by having the same circuitry in the line mounted device except that the line mounted device has an additional current transformer operative to transform the relatively higher current levels in the power line 170 to a lower current level compatible with the rest of the sensor circuitry. In addition, the ground sensor 105a may have conventional powering means whereas the line mounted sensor has powering means as previously described. Although the ground sensor 105a can be powered as previously described. Therefore, the sensing characteristics of the line mounted device 105 and the ground sensor 105a are very similar which allows transfer characteristics of the legacy current transformer 480 such as non-linearity, phase shift, frequency response, etc. to be isolated.

Since the line mounted device 105 and the ground sensor 105a, may have the same time/position circuitry 120 (such as a GPS receiver), both may sample a parameter (such as current) of the power line 170 at the same time. Alternatively, only one of line mounted device 105 and ground sensor 105a may have time/position circuitry 120 and time information may be transferred from one to the other over the wireless communications link.

Differential techniques for position determination may be used for determining sag in the power line 170. For example, GPS systems typically have an absolute position error in the order of approximately 10 meters, but the relative error between two GPS receivers located relatively close to each other may be much less than this. Therefore, using the relative change in height position between the stationary ground sensor 105a and the potentially moving line mounted device 105, an accurate determination of line sag may be determined. The ground sensor 105a and the line mounted device 105 can be separated by various distances that may range, by way of example, from meters to kilometers.

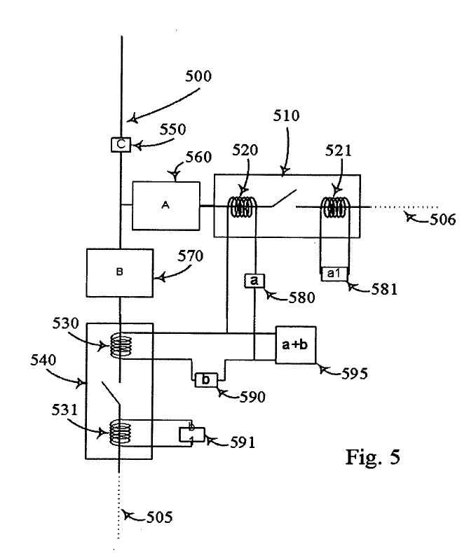

Referring to FIG. 5, a portion of a substation bus system is shown incorporating breakers 510 and 540. This diagram may be representative of a one line diagram of a portion of a “breaker and a half” or “ring bus” structure in a substation. A transmission line 500 enters the substation and power flow is split between two busses or lines 505 and 506 which connect to additional structures within the substation (not shown.)

An installer has a choice of where to install line mounted devices 105. The line mounted device may be installed in position A 560, position B 570, position C 550, or another location in the substation or on a transmission line. The ground sensor 105a may be installed in position a 580, position b 590, position a1 581, position b1 591, position a+b 595 or another location in the substation. As will be seen in the following discussion, the position of mounting of the line mounted device 105 and ground sensor 105a may have a significant impact on the operation of the system.

Breakers 510 and 540 generally contain a number of CTs 520, 521, 530, 531 which are often referred to as bushing CTs. These CTs may be supplied as a part of the breaker by the breaker manufacturer and are often optimized for protective relaying functions. For instance if a protective relay is installed in position a+b 595, it can protect against faults on the transmission line due to the summing effect of connecting the secondaries of CTs 520 and 530 together. Breakers often contain multiple CTs and often there are spares which the substation may not initially be using (such as CTs 521 and 531).

If the line mounted device 105 is installed only in position C 550, it can accurately measure characteristics of the transmission line 500. This position may make it difficult to reclassify CTs 520, 521, 530, 531 since the current flow in the transmission line divides between the two breakers. Similarly a ground sensor mounted in position a+b 595 will see the sum of the currents in the two breakers, but will not be able to determine the operating point of the individual CTs 520, 530. Therefore, it will be difficult to reclassify the CTs 520, 530 due to the fact that the magnitude and phase characteristics of CTs is generally variable based on flux level in the CT core. Often in a legacy substation, protective relaying and metering is installed in the position a+b 595 only.

In order to reclassify a CT, it is generally desirable to install the line mounted device 105 in position A 560 and the ground sensor 105a in location a 580 or position al 581. At the same time or a different time, a line mounted device 105 may be installed in position B with a ground sensor 105a installed in position b 590 or, position b1 591. This allows direct monitoring of current flow through the CT to be reclassified (e.g., CT 520).

A new metering device may have to be installed in positions a 580, a1 581, b 590 or b1 591 after the reclassification process is complete. If new metering devices are installed in at least one of positions a 580 and a1 581 and positions b 590 and b1 591 it may be possible to combine the output of these two metering devices in software to derive the current or power flow through transmission line 500. Alternatively, a metering device may comprise the ground sensor 105a and therefore, the ground sensor 105a may remain installed after the reclassification process.

The aforementioned system can be used to enable a utility to maximize usage of its assets. For instance, a power line, breaker, transformer, etc. can be run very close to its maximum specification if the current flow through that asset is accurately monitored in addition to other parameters such as wind speed, temperature, humidity, etc.

The aforementioned system can be used by a utility to satisfy Sarbanes-Oxley requirements since very accurate measurements of power flow throughout the utility's system can be realized.

If the line mounted device 105 contains a CT that is coupleable to the power line 170, the line mounted device may be able to induce current into the power line 170. This current injection may be used to stimulate a second line mounted device 105. For instance, if the power line 170 is otherwise unenergized, one line mounted device may induce a current into the power line which excites both a second line mounted device 105 and the legacy instrumentation 180. This current may be used in the reclassification process. The amount of current that can be injected and the amount of time it can be injected for may depend on the amount of power available to the line mounted device 105. The line mounted device may store energy over a period of time in supercapacitors and then convert this energy to current in a second time period. The current injection may be performed at different frequencies in order to characterize the frequency response of the legacy instrumentation 180.

Instead of or in addition to exciting a second line mounted device 105 for reclassification purposes, current injection may be used for communication over the power line 170.

It may not be possible to have the power line 170 transition through all conditions for which reclassification of the legacy instrumentation is desired. For instance, all voltage, current, power, temperature, harmonic content, etc. conditions may not be realizable in a reasonable time or it may be difficult or expensive to transition the power line 170 through all possible conditions in order to produce compensation characteristics over the entire desired range. Therefore, the microprocessor based device 160 (or another device) may contain characterization data for typical legacy instrumentation 180. For instance, if it is not possible to transition the power line 170 through all current levels, but it is known that the current transformers within the legacy instrumentation are of a certain manufacturer/type, the characterization data from the current levels that are realizable may be compared to the typical data for that model/type. If the data correlates for the realizable current levels, it is reasonable to assume that it will correlate for the un-realizable current levels also. Even if the manufacturer/type of legacy instrumentation 180 is not known (which may for instance occur when a CT is built into a breaker) it may be possible to identify the manufacturer/type based on its characterization data for a limited range of current levels.

It is therefore intended that the foregoing detailed description be regarded as illustrative rather than limiting, and that it be understood that it is the following claims, including all equivalents, that are intended to define the spirit and scope of this invention.

1. In a system where legacy instrumentation monitors at least one power parameter of a power line, a method for reclassifying the legacy instrumentation, the method comprising:
coupling a first monitoring device to the power line while the power line is in operating condition;
interfacing a second monitoring device to the legacy instrumentation;
generating first data representing at least one power parameter of the power line with the first monitoring device;
generating second data representing the at least one power parameter at the legacy instrumentation using the second monitoring device; and
identifying transfer characteristics of the legacy instrumentation based on at least the first data and the second data.

2. The method of claim 1, wherein the second monitoring device has a sensor input operative to receive a limited range of operation of the legacy instrumentation, further comprising at least one of:
reclassifying the legacy instrumentation for a particular range of operation based on the limited range of operation of the legacy instrumentation and on a manufacturing type of the legacy instrumentation; and
identifying transfer characteristics of the legacy instrumentation over a limited range of operation of the legacy instrumentation by estimation or by comparison of the identified transfer characteristics with a database of transfer characteristics in order to reclassify the legacy instrumentation for the larger range of operation.

3. The method of claim 1, wherein generating first data representing at least one power parameter of the power line with the first monitoring device further comprises:
associating a first indication of time with the first data; and
associating a second indication of time with the second data.

4. The method of claim 3, further comprising:
receiving at least one of said first indication of time and said second indication of time from at least one of a GPS satellite, a cellular telephone network and an atomic clock.

5. The method of claim 1, wherein identifying transfer characteristics of the legacy instrumentation based on at least the first data and the second data further comprises isolating the transfer characteristics of a current transformer, wherein the transfer characteristics include one or more of, a non-linearity of the current transformer, a phase shift of the current transformer, and a frequency response of the current transformer.

6. The method of claim 1, further comprising producing compensation data operative to be applied to the second data, the compensation data generated by a comparison between the first data and the second data.

7. The method of claim 1, further comprising including one or more of wind speed, temperature, and humidity in the first data and in the second data.

8. The method of claim 7, further comprising transitioning the power line through one or more conditions for which reclassification is desired, wherein the one or more conditions include one or more of voltage, current, power, temperature, and harmonic content.

9. A method for reclassifying a current transformer in legacy instrumentation, the method comprising:
connecting a first monitoring device on a bus line associated with a particular transmission line, wherein the bus line includes one or more current transformers;
connecting a second monitoring device on a secondary of a particular current transformer, wherein the first monitoring device has a first current input specification and the second monitoring device has a second current input specification that is different from the first current input specification;
determining transfer characteristics of the particular current transformer by comparing first data measured by the first monitoring device for current in the bus line with second data measured by the second monitoring device; and
reclassifying the particular current transformer based on the transfer characteristics.

10. The method of claim 9, further comprising:
measuring one or more of a magnitude and a phase characteristics of current in the bus line with the first monitoring device, wherein the one or more of the magnitude and phase characteristics are included in the first data;
measuring one or more of the magnitude and the phase characteristics of the current in the secondary of the particular current transformer with the second monitoring device for inclusion in the second data.

11. The method of claim 9, further comprising installing a first metering device such that the metering device is coupled with the secondary of the particular current transformer.

12. The method of claim 11, further comprising:
reclassifying a separate current transformer on a second bus line by connecting the second monitoring device to a secondary of the separate current transformer and connecting the first monitoring device to a bus line associated with the separate current transformer;
installing a second metering device at the secondary of the separate current transformer; and
combining the output of the first metering device and the second metering device to derive current in the transmission line.

13. The method of claim 9, further comprising connecting the second monitoring device with a secondary of a separate current transformer connected with a separate bus line associated with the transmission line.

14. The method of claim 9, further comprising monitoring additional parameters with at least one of the first line device and the second line device, the additional parameters including one or more of wind speed, temperature, and humidity.

15. The method of claim 14, further comprising maximizing use of at least one of a transmission line, a breaker, and a current transformer by ensuring a current that is substantially equal to a maximum for the at least one of the transmission line, the breaker, and the current transformer by monitoring the current with at least one of the first monitoring device and the second monitoring device.

16. The method of claim 9, further comprising transitioning the particular current transformer through one or more conditions for which reclassification of the particular current transformer is desired, wherein the one or more conditions include one or more of voltage, current power, temperature, and harmonic content.

17. The method of claim 9, further comprising inducing a current into the particular transmission line or the bus line with a line mounted device.

18. The method of claim 17, further comprising one or more of:
inducing the current at multiple frequencies;
storing energy in at least one supercapacitor, the energy used to induce the current.

19. In an environment where legacy instrumentation monitors at least one power parameter of a power line, a system for reclassifying the legacy instrumentation, the system comprising:
a first monitoring device operative to couple to the power line and monitor at least one parameter of the power line, the first monitoring device generating first data indicative of the at least one parameter of the power line;
a second monitoring device operative to interface with the legacy instrumentation and monitor the at least one parameter of the power line at the legacy instrumentation, the second monitoring device generating second data indicative of the at least one parameter of the power line at the legacy instrumentation; and
a microprocessor based device coupled with the first monitoring device and with the second monitoring device, wherein the microprocessor based device identifies one or more transfer characteristics of the legacy instrumentation based on the first data and the second data.

20. The system of claim 19, wherein the first monitoring device comprises time circuitry operative to provide indications of time to be associated with the at least first data and wherein the second monitoring device comprises time circuitry operative to provide indications of time to be associated with at least the second data.

21. The system of claim 20, wherein the one or more transfer characteristics further comprise one or more of non-linearity of a current transformer, phase shift of the current transformer, and frequency response of the current transformer.

22. The system of claim 19, wherein the first monitoring device comprises a first global positioning receiver and the second monitoring device comprises a second global positioning receiver.

23. The system of claim 19, wherein one of said first monitoring device and said second monitoring device comprises accurate time circuitry and the other of said first monitoring device and said second monitoring device receives an indication of time over a wireless link from said one.

24. The system of claim 19, wherein circuitry of the first monitoring device is substantially similar to circuitry of the second monitoring device, wherein the first monitoring device has a current transformer adapted to monitor current in the power line and the second monitoring device is adapted to monitor current in the legacy instrumentation.

25. The system of claim 24, wherein the first monitoring device further comprises a current transformer operative to transform higher current levels in the power line to a lower current level compatible with the first monitoring device and wherein the second monitoring device comprises a sensor input operative to receive a signal range of the legacy instrumentation.

26. The system of claim 19, wherein the microprocessor based device further comprises wireless communication circuitry that enable a wireless connection with at least one of the first monitoring device and the second monitoring device.

27. In a power station that includes one or more current transformers, a system for reclassifying a current transformer, the system comprising:
a first line mountable monitoring device operative to couple with a particular bus line in the power station, the first line mountable monitoring device generating first characteristics relating to current in the particular bus line;
a second monitoring device operative to couple with a secondary of a particular current transformer connected with the particular bus line, the second monitoring device generating second characteristics relating to current in the particular current transformer; and
a microprocessor device coupled with the first line mountable monitoring device and the second monitoring device such that current flow through the particular current transformer is characterized using the first characteristics and the second characteristics.

28. The system of claim 27, wherein the particular bus line is coupled to one or more transmission lines.

29. The system of claim 27, wherein the particular bus line is included in a ring bus structure in the power station.

30. The system of claim 27, wherein the microprocessor device determines magnitude and phase characteristics of current in the particular current transformer based on the first characteristics and the second characteristics.

31. The system of claim 27, wherein the microprocessor device reclassifies the particular current transformer.

32. The system of claim 27, further comprising a metering device coupled to the particular current transformer.

33. The system of claim 27, further comprising at least one of:
a third monitoring device connected with a secondary of a separate current transformer on a separate bus line; and
a second metering device connected with the secondary of the separate current transformer.

34. The system of claim 33,
wherein the first line mountable monitoring device comprises:
a sensor operative to interface with the particular bus line and produce data indicative of at least the current in the particular bus line, wherein the data is processed by a processor to produce the first characteristics; and
wireless communication circuitry coupled with the processor and operative to transmit the first characteristics to the microprocessor device;
wherein the second line device comprises:
a sensor operative to interface with the secondary of the current transformer and produce data indicative of at least the current in the current transformer, wherein the data is processed by a processor to produce the second characteristics; and
wireless communication circuitry coupled with the processor and operative to transmit the second characteristics to the microprocessor device; and
wherein the third monitoring device comprises:
a sensor operative to interface with the secondary of the separate current transformer and produce data indicative of at least the current in the separate current transformer, wherein the data is processed by a processor to produce third characteristics; and
wireless communication circuitry coupled with the processor and operative to transmit the third characteristics to the microprocessor device when the line mountable monitoring device is coupled with the separate bus line.

35. The system of claim 27, wherein the second line device is coupled with a secondary of a separate current transformer.

36. A method for correcting power parameters measured by legacy instrumentation, the method comprising:
attaching a line device to a transmission line, the line device including a sensor;
monitoring one or more power parameters of the transmission line with the line device;
detecting a transient condition in the transmission line with the line device;
determining if characteristics of the legacy instrumentation have changed in response to the transient condition; and
reclassifying the legacy instrumentation if the characteristics of the legacy instrumentation have changed using the line device.

37. The method of claim 36, wherein detecting a transient condition in the transmission line with the sensor further comprises at least one of:
detecting a current surge; and
detecting a new level of harmonics.

38. The method of claim 36, further comprising discarding one or more prior comparisons between output of the legacy instrumentation and the line device if the characteristics of the legacy instrumentation have changed.

39. The method of claim 38, further comprising identifying a steady state condition which indicates that at least some of the prior comparisons are unusable for reclassifying the legacy instrumentation or for correcting the output of the legacy instrumentation.

40. The method of claim 39, wherein the steady state condition is a high level of harmonics.

41. The method of claim 36, further comprising:
removing the line device from the transmission line;
verifying that the line device is accurate in order to validate the reclassification of the output of the legacy instrumentation;
recalibrating the line device if the line device is not verified.

42. The method of claim 41, further comprising verifying that the line device is accurate by comparing an output of the line device with respect to a current with a known magnitude and a known phase.
